(19) United States
(12) Patent Application Publication
(10) Pub. No.: US 2015/0070822 A1
(43) Pub. Date: Mar. 12, 2015

(54) ELECTRONIC DEVICE AND SUBSTRATE CONTAINER

(71) Applicant: FUJITSU LIMITED, Kawasaki-shi (JP)

(72) Inventor: Masayoshi HIRANO, Yokohama (JP)

(21) Appl. No.: 14/473,133

(22) Filed: Aug. 29, 2014

(30) Foreign Application Priority Data
Sep. 12, 2013 (JP) 2013-189552

(51) Int. Cl. H05K 7/14; B65G 35/00; H05K 7/16

(52) U.S. Cl. CPC H05K 7/1427; H05K 7/16; B65G 35/00
USPC 361/679.01; 414/222.01

(57) ABSTRACT

An electronic device includes: a housing; a holder configured to support a first substrate and is inserted into the housing; a second substrate disposed in the housing, at a side with respect to a direction in which the holder is inserted; and a mechanism configured to move the first substrate in the direction with the second substrate and to connect the first substrate to the second substrate.

### CROSS-REFERENCE TO RELATED APPLICATION

This application is based upon and claims the benefit of priority of the prior Japanese Patent Application No. 2013-189552, filed on Sep. 12, 2013, the entire contents of which are incorporated herein by reference.

### FIELD

The embodiments discussed herein are related to an electronic device and a substrate container.

### BACKGROUND

In some configurations, a backplane printed board assembly is adopted to receive a plurality of storage devices with threads leading out of an opening in a housing.

In the housing, into which a main substrate is to be inserted, if a connection substrate, to which the main substrate is to be connected, is located to a near side or a far side with respect to the direction in which the main substrate is inserted (insertion direction), the flow of cooling air in the insertion direction is subjected to resistance.

The following is a reference document.
[Document 1] Japanese Laid-open Patent Publication No. 2013-45440.

### SUMMARY

According to an aspect of the invention, an electronic device includes: a housing; a holder configured to support a first substrate and is inserted into the housing; a second substrate disposed in the housing, at a side with respect to a direction in which the holder is inserted; and a mechanism configured to move the first substrate in the direction with the second substrate and to connect the first substrate to the second substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of an electronic device according to a first embodiment;

FIG. 2 is a front view of the electronic device according to the first embodiment;

FIG. 3A is a perspective view of a substrate unit according to the first embodiment;

FIG. 3B is a perspective view of the substrate unit according to the first embodiment;

FIG. 3C is a perspective view of the substrate unit according to the first embodiment;

FIG. 4A is a plan view of the inside of the substrate unit according to the first embodiment;

FIG. 4B is a plan view of the inside of the substrate unit according to the first embodiment;

FIG. 4C is a plan view of the inside of the substrate unit according to the first embodiment;

FIG. 5A is a plan view of the electronic device according to the first embodiment;

FIG. 5B is a plan view of the electronic device according to the first embodiment;

FIG. 5C is a plan view of the electronic device according to the first embodiment;

FIG. 6 is a sectional view taken along line 6-6 in FIG. 3A;

FIG. 7A is a perspective view of a substrate unit according to a second embodiment;

FIG. 7B is a perspective view of the substrate unit according to the second embodiment;

FIG. 7C is a perspective view of the substrate unit according to the second embodiment;

FIG. 8A is a plan view of the inside of the substrate unit according to the second embodiment;

FIG. 8B is a plan view of the inside of the substrate unit according to the second embodiment;

FIG. 8C is a plan view of the inside of the substrate unit according to the second embodiment; and

FIG. 9 is a diagram of the substrate unit illustrated in FIG. 8A, as viewed from an arrow 9 direction.

### DESCRIPTION OF EMBODIMENTS

A first embodiment will be described in detail below with reference to the drawings.

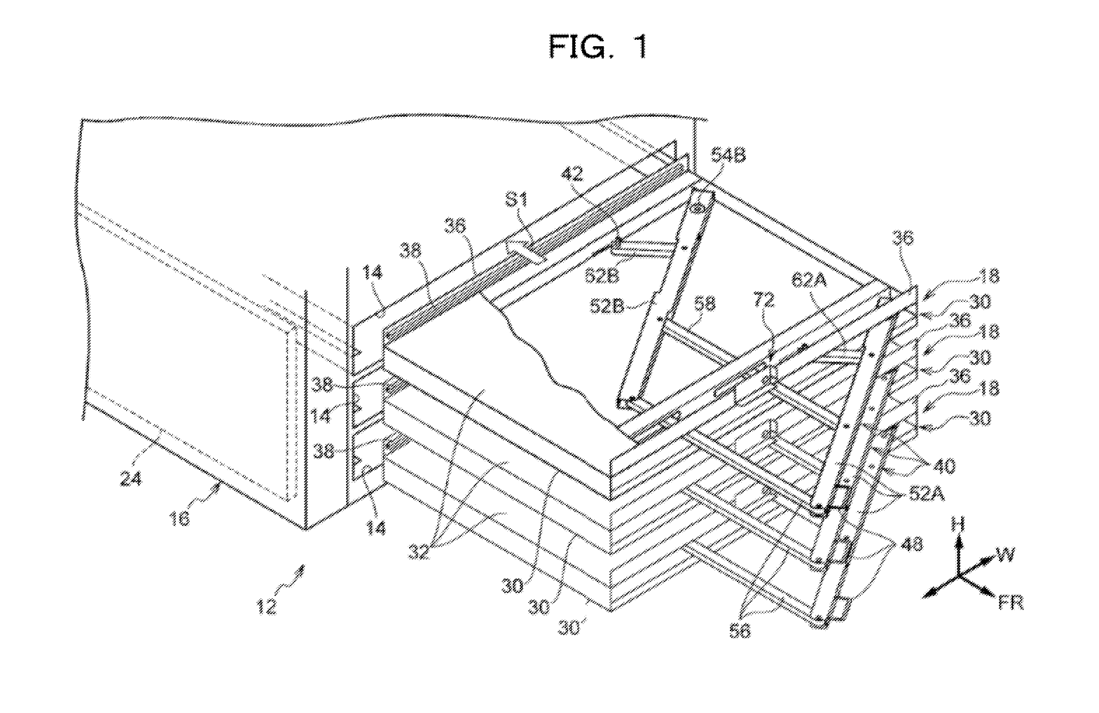

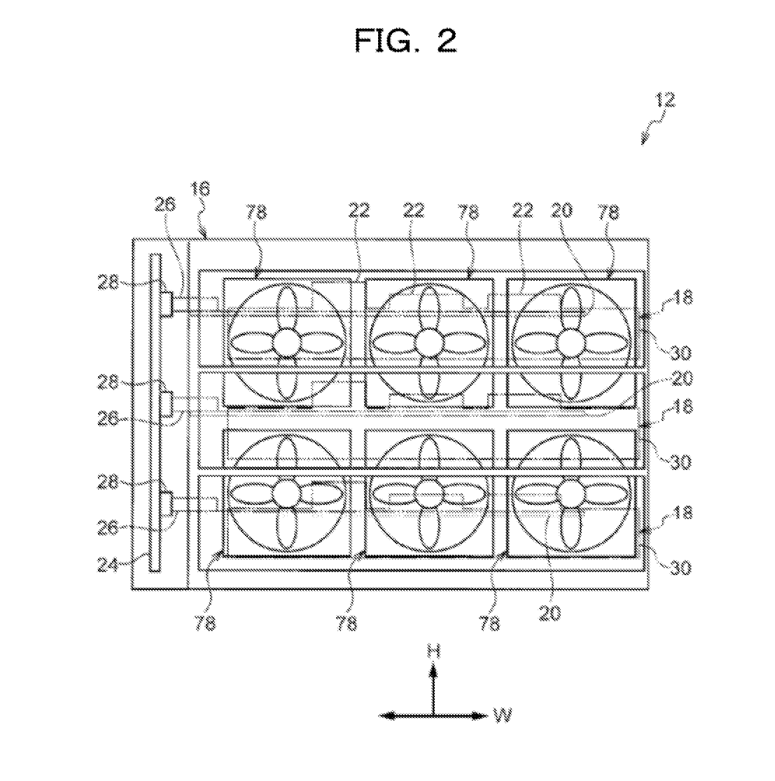

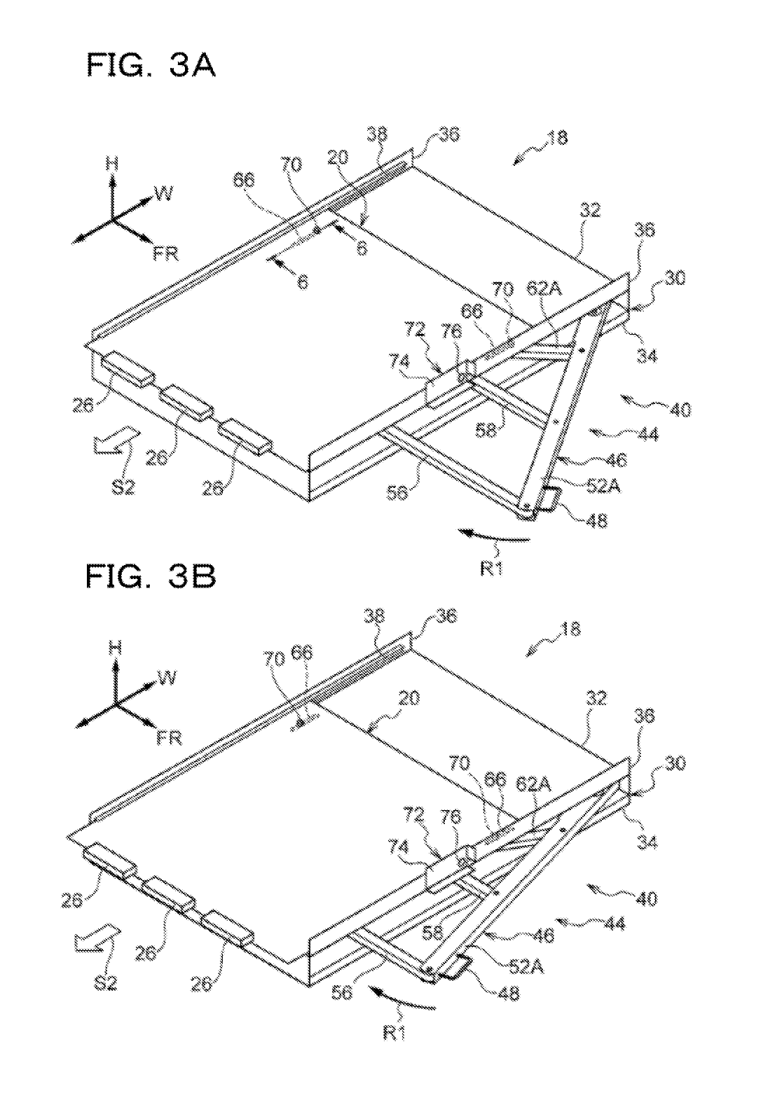

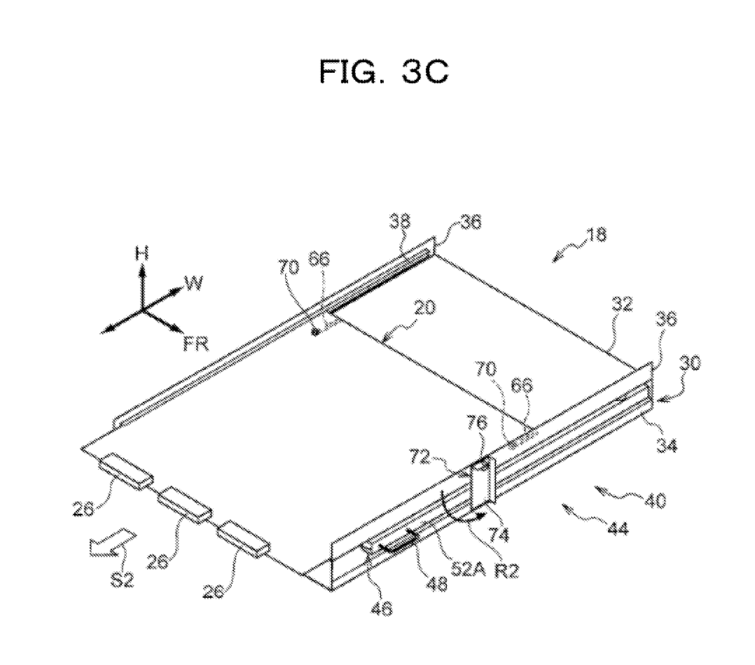

FIGS. 1 and 2 illustrate an electronic device 12 according to a first embodiment. FIGS. 3A to 3C illustrate a substrate unit 18. In each drawing, the front, width, and height directions of the electronic device 12 are denoted by arrows FR, W, and H, respectively. These directions are for ease of explanation, and not for limiting the directions in an actual use situation of the electronic device 12.

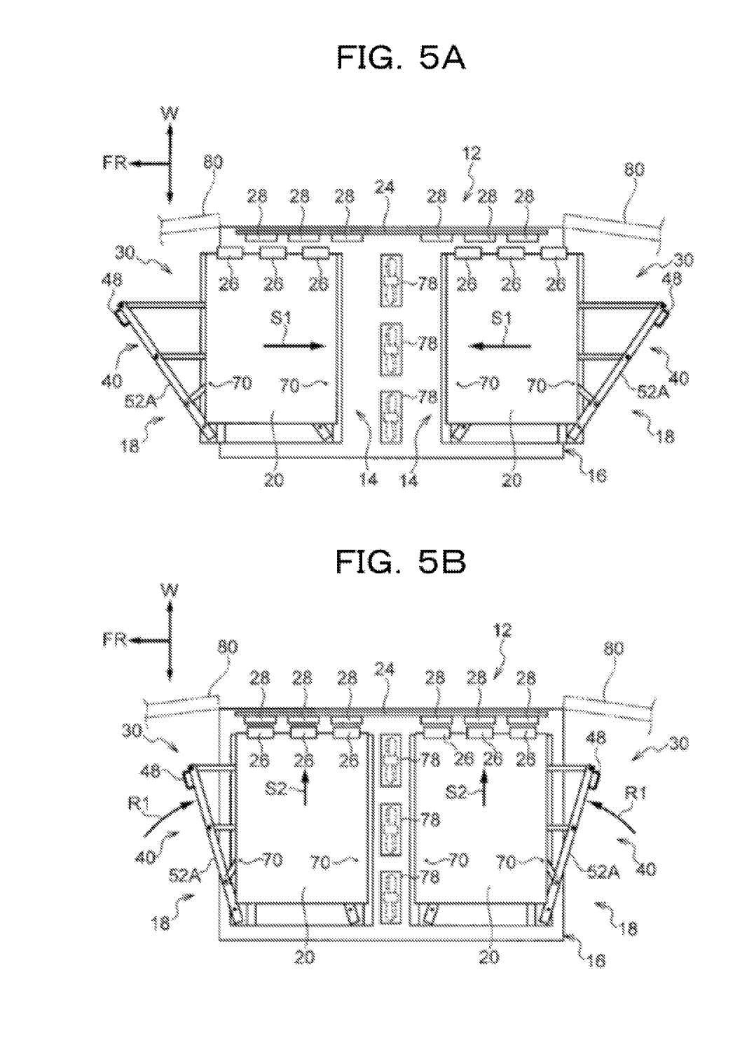

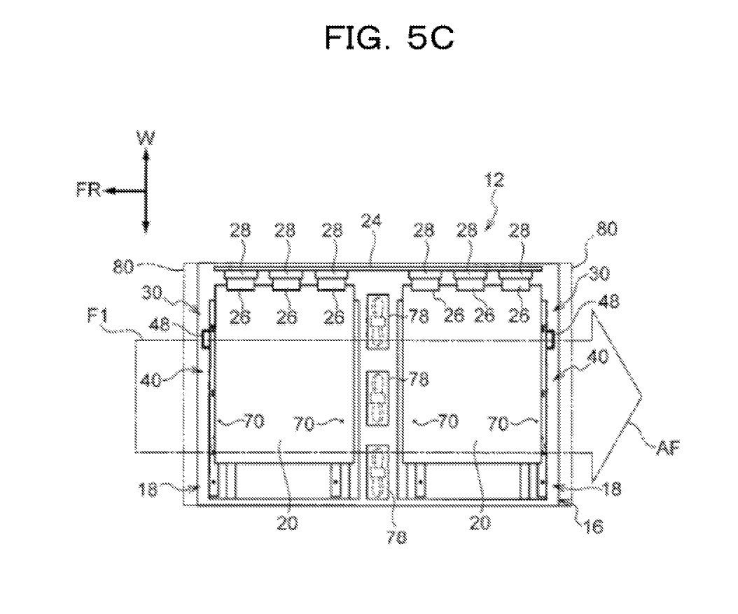

As illustrated in FIG. 1, the electronic device 12 has a housing 16. The housing 16 has insertion portions 14 into which the substrate units 18 are inserted in an arrow S1 direction and are accommodated. As illustrated, in particular, in FIGS. 5A to 5C, the electronic device 12 according to this embodiment is configured such that the substrate units 18 are inserted from both the front side (i.e., left side in FIG. 5A) and the rear side (i.e., right side in FIG. 5A) of the housing 16. In this embodiment, when the substrate units 18 are inserted into the housing 16, the substrate units 18 on the front side are handled in front of the substrate units 18, and the substrate units 18 on the rear side are handled behind the substrate units 18. In the following description, the side at which the substrate units 18 are handled will be referred to as, simply, “near side”. The substrate units 18 to be inserted from the rear side may have a configuration in which, for example, the positions of members and parts thereof are inverted from those of the substrate units 18 to be inserted from the front side.

Furthermore, as illustrated in FIG. 1, in this embodiment, a plurality of (three, in the example in FIG. 1) substrate units 18 are inserted into the housing 16 in the height direction. As mentioned above, because the substrate units 18 are inserted from both the front side and the rear side of the housing 16, the total number of the substrate units 18 is six. Note that the number of the substrate units 18 may be one.

As illustrated in FIGS. 3A to 3C, the substrate units 18 each support a main substrate 20. The main substrate 20 carries electronic components 22, such as various devices, as illustrated in FIG. 2.

The housing 16 accommodates a connection substrate 24. The connection substrate 24 is disposed at a side of the substrate units 18 with respect to the insertion direction (arrow S1 direction). In the housing 16, the main substrates 20 are electrically connected to the connection substrate 24 via connectors 26 and 28. Note that the “side” includes either one or both of the right side and the left side with respect to the insertion direction of the substrate units 18. For example, the connection substrate 24 is located on the left side with respect to the insertion direction of the substrate units 18 that are inserted from the near side in FIG. 5A, whereas the connection substrate 24 is located on the right side with respect to the insertion direction of the substrate units 18 that are inserted from the far side.

The substrate units 18 each have a unit base 30 that supports the main substrate 20. As illustrated in detail in FIGS. 3A to 3C, the unit base 30 has a rectangular top plate 32 that is larger than the main substrate 20 in plan view and has a rectangular bottom plate 34 arranged parallel to the top plate 32.

A pair of upright plates 36 is attached to the long sides of the top plate 32. The main substrate 20 is supported between the upright plates 36. As will be described below, in the housing 16, the main substrate 20 slides sideways (in this embodiment, particularly in the perpendicular direction) with respect to the direction in which the substrate unit 18 is inserted into the housing 16 (i.e., arrow S1 direction); that is, the main substrate 20 slides in a direction in which the substrate unit 18 is connected to the connection substrate 24 (arrow S2 direction).

The upright plates 36 each have a rail groove 38 in their opposing faces. By fitting the edges of the main substrate 20 into the rail grooves 38, the main substrate 20 may be slid without rattling.

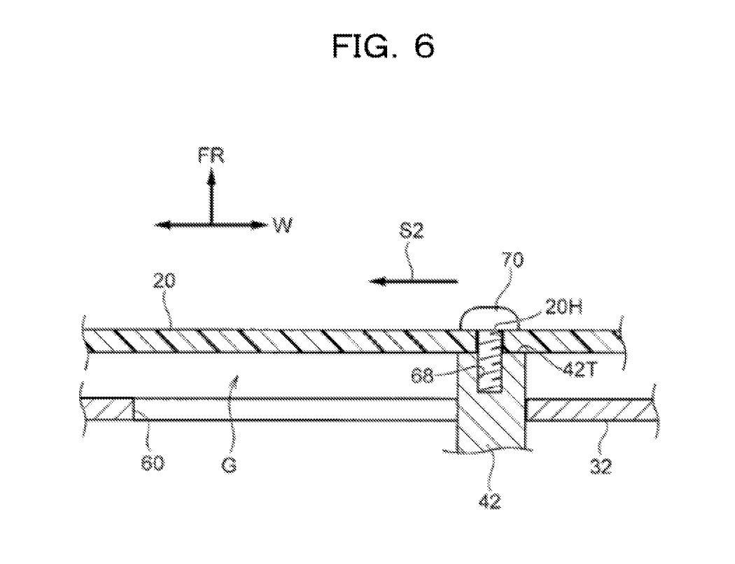

The electronic device 12 has a moving mechanism 40. In particular, in the first embodiment, the moving mechanism 40 has fixing pins 42 (see FIG. 6) and a manipulation member 44 and is provided on the unit base 30. This moving mechanism 40 enables the main substrate 20 to move (slide) sideways (in the arrow S2 direction in FIGS. 3A to 3C) and to be connected to the connection substrate 24 in the housing 16.

The manipulation member 44 includes a link mechanism 46, a grip 48, and a conversion mechanism 50. The link mechanism 46 is provided between the top plate 32 and the bottom plate 34.

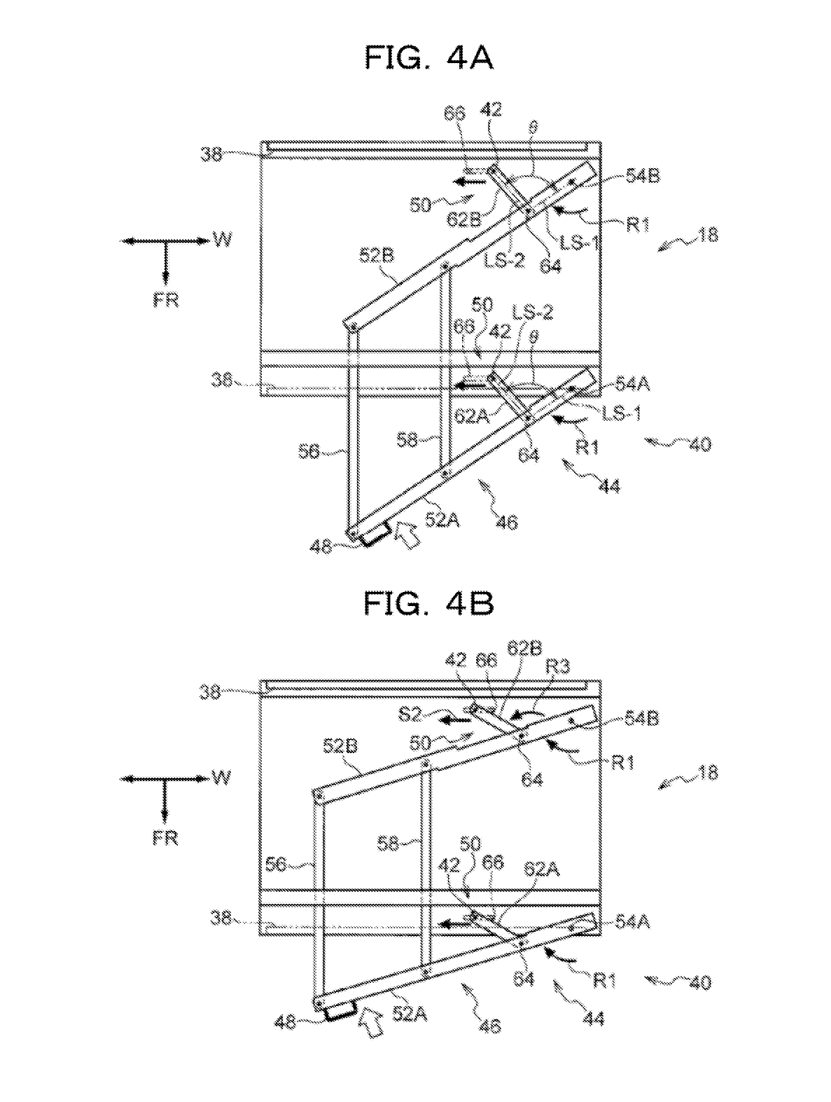

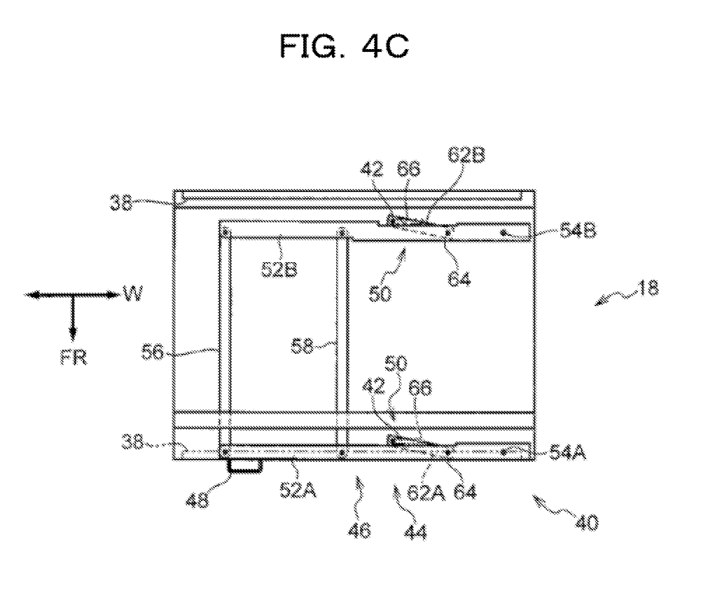

The link mechanism 46 according to the first embodiment includes, as illustrated in detail in FIGS. 4A to 4C, a pair of first arms 52A and 52B. Ends of the first arms 52A and 52B are attached to the top plate 32 by shafts 54A and 54B, and the other ends of the first arms 52A and 52B are rotated about the shafts 54A and 54B.

When the first arm 52A, located on the near side, is rotated about the shaft 54A, the other end thereof changes its position between a projected position where it is projected to the near side from the unit base 30, as illustrated in FIGS. 3A and 4A, and a stored position where it is stored in the unit base 30, as illustrated in FIGS. 3C and 4C.

On the other hand, the first arm 52B remains stored in the unit base 30 even when it is rotated about the shaft 54B.

The shafts 54A and 54B are provided on the upstream side in the sliding direction of the main substrate 20 (arrow S2 direction). The pair of first arms 52A and 52B are coupled together by coupling arms 56 and 58 at their ends (i.e., the portions on the other side of the shaft 54A) and middle portions, respectively, so, the first arms 52A and 52B remain parallel.

The link mechanism 46 further includes a pair of second arms 62A and 62B. Ends of the second arms 62A and 62B are attached to the middle portions of the first arms 52A and 52B by shafts 64, and the other ends of the second arms 62A and 62B are rotatable. Fixing pins 42 are attached to the other ends of the second arms 62A and 62B.

The fixing pins 42 are an example of a fix member. In this embodiment, two fixing pins 42 in total are provided (i.e., one for the second arm 62A and the other for the second arm 62B). As illustrated in FIG. 6, the top plate 32 has elongated holes 66 extending in the sliding direction of the main substrates 20, and the fixing pins 42 are accommodated therein.

The fixing pins 42 each have, at its top, a contact step portion 42T that comes into contact with the lower surface of the main substrate 20. The contact step portion 42T is provided with a female screw 68. The main substrate 20 is provided with a fixing hole 20H. By inserting a male screw 70 through the fixing hole 20H and screwing it into the female screw 68, the fixing pin 42 is fixed to the main substrate 20. Because there is a gap G between the main substrate 20 and the top plate 32, the main substrate 20 and the top plate 32 do not rub each other when the main substrate 20 is slid, as will be described below.

Now, an angle θ, illustrated in FIG. 4A, formed between a line segment LS-1 extending between the shaft 64 and the shaft 54A or 54B and a line segment LS-2 extending between the shaft 64 and the fixing pin 42 will be considered. The angle θ is an obtuse angle when the first arm 52A is at a projected position. When the first arms 52A and 52B are rotated in the arrow R1direction, the angle θ increases, and the second arms 62A and 62B are rotated in the arrow R3 direction.

The fixing pins 42 are accommodated in the elongated holes 66. Hence, the fixing pins 42 slide in the arrow S2 direction (sideways) as the first arms 52A and 52B are rotated in the arrow R1 direction. More specifically, the conversion mechanism 50 has the second arms 62A and 62B and the elongated holes 66, and the second arms 62A and 62B serve as part of the link mechanism 46 and part of the conversion mechanism 50.

Of the two first arms 52A and 52B, the first arm 52A on the near side has a grip 48 at an end, which protrudes toward the near side of the first arm 52A. The grip 48 makes it easy to rotate the first arm 52A.

A lock member 72 that keeps the link mechanism 46 (first arm 52A) accommodated inside the unit base 30 is attached to the upright plate 36 on the near side of the unit base 30. The lock member 72 includes a plate-shaped lock plate 74 and a supporting shaft 76 that rotatably supports the lock plate 74 on the upright plate 36.

As illustrated in FIGS. 3A and 3B, in an orientation in which the lock plate 74 is rotated upward (i.e., non-lock orientation), the lock plate 74 is not positioned in the space between the top plate 32 and the bottom plate 34. Hence, the first arm 52A is able to pass through this space. On the other hand, in an orientation in which the lock plate 74 is rotated in an arrow R2 direction (i.e., lock orientation), as illustrated in FIG. 3C, the lock plate 74 is positioned in the space between the top plate 32 and the bottom plate 34. Therefore, the first arm 52A stored inside the unit base 30 comes into contact with the lock plate 74 when rotated toward the outside of the unit base 30 (the direction opposite to the arrow R1 direction), and thus, the rotation thereof is restricted.

As illustrated in FIGS. 2 and 5A to 5C, blower fans 78 are provided in the housing 16. The blower fans 78 illustrated in FIGS. 5A to 5C are disposed in the middle of the housing 16 in the front-rear direction, that is, between the substrate units 18 to be inserted from the front side and the substrate units 18 to be inserted from the rear side. When driven, the blower fans 78 generate airflow in the front-rear direction (i.e., an arrow F1 direction or the opposite direction) in the housing 16.

The blower fans 78 may be disposed at a position other than the middle of the housing 16 in the front-rear direction. For example, in a configuration in which the substrate units 18 are arranged only on the front side or only on the rear side in the housing, the depth of the housing may be reduced. In such a housing with a reduced depth, by arranging the blower fans 78 on the opposite side from the first arms 52A of the substrate units 18, a configuration in which the blower fans 78 are disposed on the rear side or the front side within the housing is achieved.

Although FIG. 2 illustrates an example in which six blower fans 78 in total are arranged (i.e., two lows in the top-bottom direction and three rows in the width direction), the number and arrangement of the blower fans 78 are not limited thereto.

As illustrated in FIGS. 5A to 5C, the housing 16 is provided with cover plates 80 on the front side and the rear side. In the example in FIGS. 5A to 5C, the cover plates 80 are rotatable relative to the housing 16 due to hinges, thereby opening or closing the insertion portions 14. The cover plates 80 are provided with ventilation openings so that the flow of air AF is not blocked.

Now, advantages of this embodiment will be explained. Before placing the main substrate 20 in the housing 16, the main substrate 20 is supported by the unit base 30. More specifically, the edges of the main substrate 20 are accommodated in the rail grooves 38. Then, as illustrated in FIG. 6, the main substrate 20 is placed on the contact step portions 42T of the fixing pins 42, and the male screws 70 are inserted into the fixing holes 20H and screwed into the female screws 68. Thus, the fixing pins 42 and the main substrate 20 are fixed together.

Before placing the main substrate 20 in the housing 16, as illustrated in FIG. 5A, the unit base 30 is drawn out of the housing 16. At this time, as illustrated in FIGS. 3A and 4A, the first arm 52A is disposed at the projected position. Furthermore, as illustrated in FIG. 3A, the lock member 72 is in a non-lock orientation.

Then, the unit base 30 (substrate unit 18) supporting the main substrate 20 in this manner is moved in the arrow S1 direction, as illustrated in FIGS. 1 and 5A, and is inserted into the insertion portion 14 of the housing 16.

As illustrated in FIG. 5B, the substrate unit 18 is inserted to a predetermined position of the housing 16. Then, the grip 48 is pulled to rotate the first arm 52A about the shaft 54A in the arrow R1 direction. Because the first arms 52A and 52B are coupled together by the coupling arms 56 and 58, the first arm 52B is also rotated in the arrow R1 direction. Furthermore, the second arms 62A and 62B are rotated about the shafts 64 in the arrow R3 direction (see FIG. 4B). Then, the fixing pins 42 slide in the arrow S2 direction.

Because the grip 48 is located to the near side of the first arm 52A (i.e., to the near side of the unit base 30 in the insertion direction), the grip 48 makes it easy to rotate the first arm 52A.

Because the fixing pins 42 are fixed to the main substrate 20, the main substrate 20 slides in the arrow S2 direction when the fixing pins 42 move in the arrow S2 direction. Because the edges of the main substrate 20 are accommodated in the rail grooves 38, rattling of the main substrate 20 when slid in the arrow S2 direction is suppressed.

As illustrated in FIG. 5C, by fitting the connectors 26 and 28 together, the main substrate 20 is electrically connected to the connection substrate 24.

At this time, the first arm 52A is at the stored position. The first arm 52B and the second arms 62A and 62B are also stored inside the unit base 30. Because the link mechanism 46 is fully accommodated in the unit base 30, it does not interfere with anything. In a configuration in which part of the link mechanism 46 projects out of the unit base 30, the cover plate 80 is provided at a position away from the unit base 30 to avoid interference with the link mechanism 46 when the cover plate 80 is closed. In contrast, in this embodiment, the cover plate 80 may be disposed at a position close to the unit base 30 inserted in the housing 16.

Furthermore, the grip 48 is located inside the housing 16. Hence, the grip 48 does not project outside the housing 16 and does not interfere with anything.

Moreover, as illustrated in FIG. 3C, the first arm 52A is kept accommodated in the unit base 30 by making the lock member 72 locked. Neither of the first arms 52A and 52B rotates in the direction opposite to the arrow R1 direction, and the fixing pins 42 do not slide in the direction opposite to the arrow S2 direction. Hence, it is possible to suppress unwanted detachment of the connectors 26 of the main substrate 20 from the connectors 28 of the connection substrate 24.

In the above-described example, the plurality of substrate units 18 are inserted and stored in the housing 16. Hence, the same operation is repeated for the number of substrate units 18.

With the substrate units 18 being accommodated in the housing 16 and the main substrates 20 being connected to the connection substrate 24, power supply from the connection substrate 24 to the main substrates 20 and signal transmission therebetween are performed. Furthermore, the main substrates 20 may be drawn out of the housing 16 for maintenance (inspection) or replacement. For example, maintenance or replacement of some substrate units 18 (main substrates 20) is possible without stopping the electronic device 12.

Furthermore, by driving the blower fans 78, a flow of air AF in the direction indicated by the arrow F1 in FIG. 5C (or in the opposite direction) is generated, cooling the electronic components 22 on the main substrates 20 (see FIG. 2).

In this embodiment, as has been described above, the substrate units 18 are inserted into the housing 16, and the main substrates 20 are moved sideways with respect to the insertion direction to be connected to the connection substrate 24. The connection substrate 24 is disposed at a side with respect to the insertion direction (arrow S1 direction) in which the substrate units 18 are inserted into the housing 16. Now, a configuration in which the connection substrate is disposed at the position of the blower fans 78, illustrated in FIGS. 5A to 5C, will be presented as a first comparative example.

In the configuration of the first comparative example, because the air AF blowing in the arrow F1 direction collides with the connection substrate from the front, the connection substrate serves as resistance to the flow of the air AF. In the configuration of the first comparative example, although it is possible to provide a hole in the connection substrate to allow the air AF to flow there through, such a hole has to be provided in the connection substrate while avoiding connectors and wires. Hence, the position and size of the hole is limited.

In contrast, in this embodiment, the connection substrate 24 is disposed at a side in the housing 16, and the main substrates 20 are moved sideways to be connected to the connection substrate 24. Because the air AF blowing in the arrow F1 direction does not collide with the connection substrate 24 from the front, ventilation resistance is low.

Now, another configuration will be presented as a second comparative example, in which the connection substrate is disposed at a side with respect to the insertion direction of the substrate unit and is configured such that it may be drawn toward the near side (front side or rear side). In the second comparative example, after the substrate unit is connected to the connection substrate drawn out of the housing, the connection substrate and the substrate unit are inserted into the housing.

In the configuration of the second comparative example, because the connection substrate is drawn out of the housing, power wires and signal wires leading to the connection substrate have to be extended correspondingly. That is, in the second comparative example, because the power wires and the signal wires leading to the connection substrate are extended, efficient power supply and high-speed signal transmission are difficult to achieve.

In contrast, in this embodiment, because the connection substrate 24 is not drawn out of the housing 16, the power wires and the signal wires leading to the connection substrate 24 may be short. Hence, compared with the configuration of the second comparative example, efficient power supply and high-speed signal transmission are possible.

When the grip 48 is pulled to rotate the first arm 52A in the direction opposite to the arrow R1 direction, because the fixing pins 42 are fixed to the main substrate 20, the main substrate 20 slides in the direction opposite to the arrow S2 direction and is disconnected from the connection substrate 24. Furthermore, by pulling the substrate unit 18 in the direction opposite to the insertion direction, the substrate unit 18 supporting the main substrate 20 may be drawn out of the housing 16.

Next, a second embodiment will be explained. In the second embodiment, components and members that are the same as those in the first embodiment will be denoted by the same reference numerals, and detailed descriptions thereof will be omitted. Furthermore, a description of an electronic device according to the second embodiment will be omitted because it may have the same configuration as the electronic device 12 according to the first embodiment.

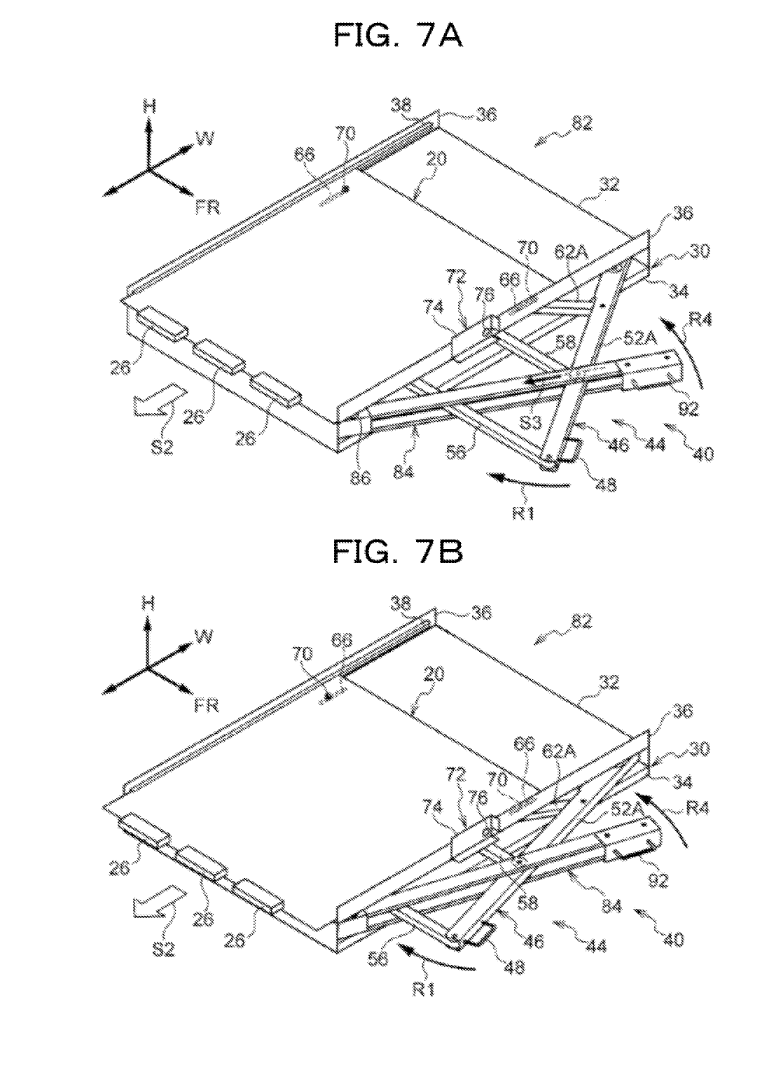

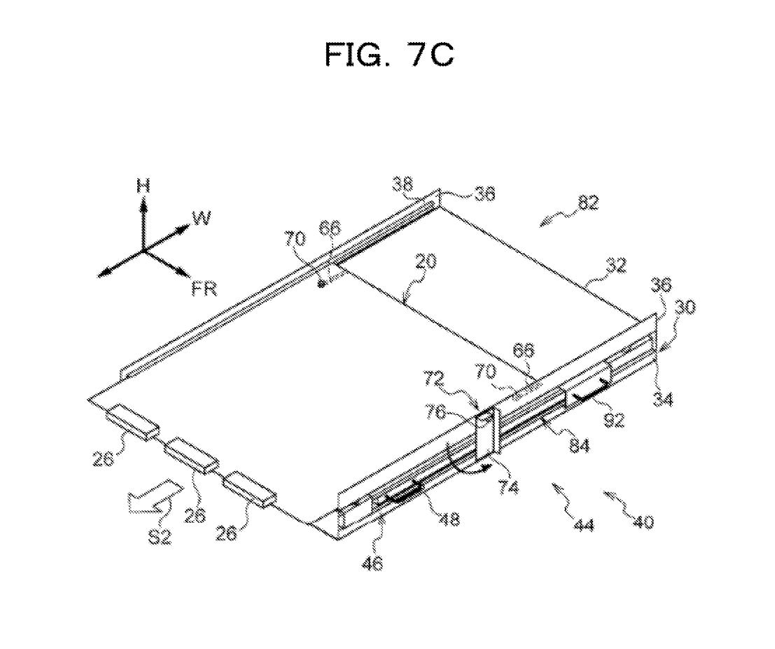

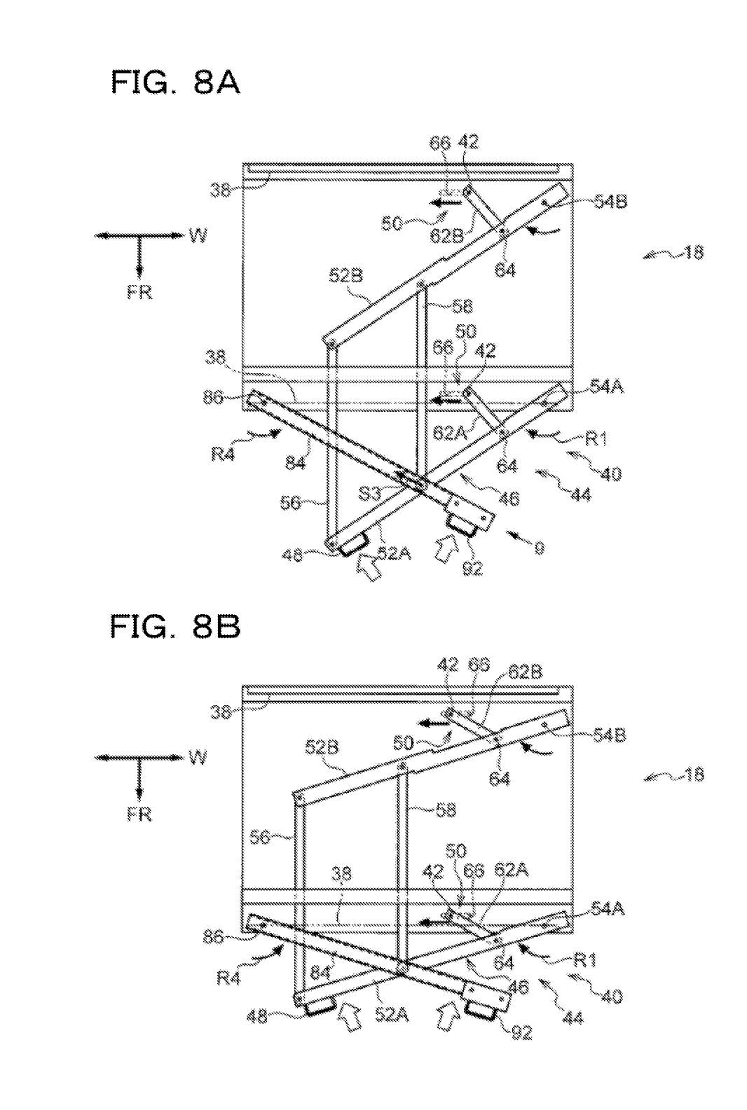

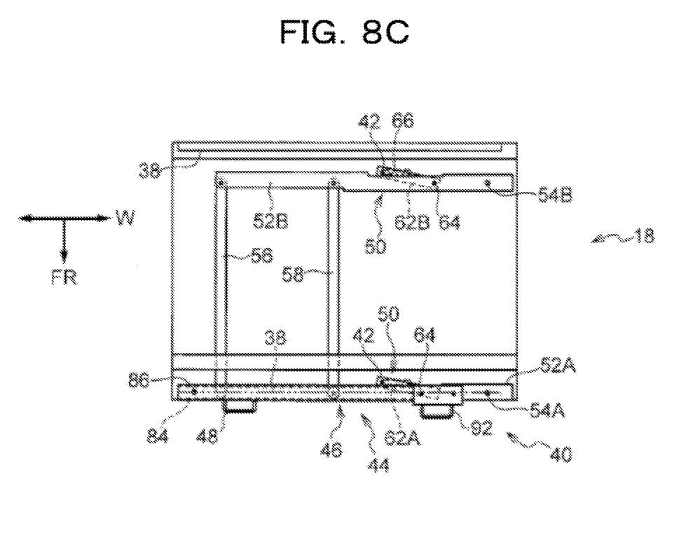

As illustrated in FIGS. 7A to 7C, a substrate unit according to the second embodiment 82 has a third arm 84, in addition to the configuration of the substrate unit 18 according to the first embodiment. The third arm 84 is attached to the top plate 32 at one end via a shaft 86 so as to be able to pivot. The other end of the third arm 84 moves between a projected position where it is projected out of the unit base 30 to the near side or far side, as illustrated in FIGS. 7A and 8A, and a stored position where it is stored in the unit base 30 after rotated about the shaft 86, as illustrated in FIGS. 7C and 8C.

The shaft 86 is provided on the downstream side in the sliding direction of the main substrates 20 (arrow S2 direction).

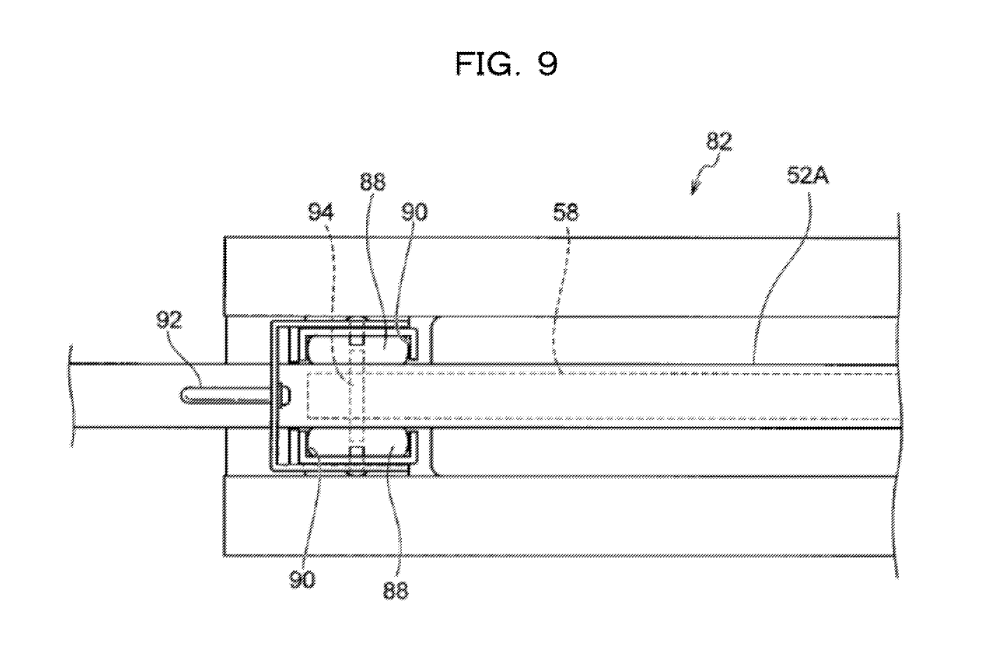

As illustrated in detail in FIG. 9, a shaft 94 passing through the coupling arm 58 and the first arm 52A in the top-bottom direction is provided at an intermediate position of the first arm 52A in the longitudinal direction. A projection 88 is attached to each of the upper and lower ends of the shaft 94. The third arm 84 has projection-accommodating grooves 90 that accommodate the projections 88 and extending in the longitudinal direction of the third arm 84.

Hence, when the third arm 84 is rotated in an arrow R4 direction (FIG. 8A), the projections 88 slide in the projection-accommodating grooves 90 in an arrow S3 direction, causing the first arm 52A to rotate in the arrow R1 direction. Conversely, when the third arm 84 is rotated in the direction opposite to the arrow R4 direction, the projections 88 slide in the projection-accommodating grooves 90 in the direction opposite to the arrow S3 direction, causing the first arm 52A to rotate in the direction opposite to the arrow R1 direction. By making the projections 88 able to rotate about the shaft 94, the friction occurring when the projections 88 slide in the projection-accommodating grooves 90 may be reduced by the rotation of the projections 88.

A grip 92 is provided at an end of the third arm 84. The grip 92 makes it easy to rotate the third arm 84.

As has been described above, in the second embodiment, two grips, 48 and 92, are provided. Either of the grips 48 and 92 enables the first arm 52A to be rotated in the arrow R1 direction and the opposite direction. That is, with either of the grips 48 and 92, the main substrate 20 may be slid in the arrow S2 direction and the opposite direction, thus making it easy to connect or disconnect the main substrate 20 to or from the connection substrate 24. Furthermore, both of the grips 48 and 92 may be pulled to rotate the first arm 52A. Hence, the force for moving the first arm 52A is distributed, reducing the force applied to each grip. Moreover, the main substrate 20 may be stably slid in the arrow S2 direction and the opposite direction.

When the two grips 48 and 92 are to be provided to achieve stable sliding of the main substrate 20 in the arrow S2 direction and the opposite direction, for example, the two grips 48 and 92 may be provided only on the first arm 52A.

In contrast, particularly in the second embodiment, not only simply the two grips 48 and 92 are provided, but the grips 48 and 92 are provided on the first arm 52A and the third arm 84, respectively, which are rotated in different directions when the main substrate 20 is slid in the arrow S1 direction. Because the shaft 54A has rotational friction, when the first arm 52A is rotated, a rotation moment in the arrow R1 direction is applied from the first arm 52A to the unit base 30. Because the shaft 86 also has rotational friction, when the third arm 84 is rotated, a rotation moment in the arrow R4 direction is applied from the third arm 84 to the unit base 30. That is, because the rotation moments applied to the unit base 30 when the first arm 52A and the third arm 84 are rotated act in the opposite directions, the moments are canceled out. Accordingly, by rotating both of the first arm 52A and the third arm 84, rotation of the unit base 30 that may occur when sliding the main substrate 20 in the arrow S2 direction is suppressed.

Although the configuration in which the manipulation member 44 includes the link mechanism 46, the grip 48, and the conversion mechanism 50 has been described, for example, a configuration in which the link mechanism 46 and the conversion mechanism 50 are not provided is also possible. That is, a configuration is possible in which links (i.e., members that pivot relative to the unit base 30), such as the first arm 52A and 52B and the second arms 62A, are not provided and in which the grip 48 is slid in the arrow S2 direction and the opposite direction, causing the fixing pins 42 to directly move in the above-mentioned direction. By using the link mechanism 46 and the conversion mechanism 50, rotational movement of the first arm 52A may be easily converted into straight movement for sliding the main substrate 20.

Moreover, as is seen from the example in FIGS. 4A and 8A, the use of the link mechanism 46 increases the length between the shaft 54A (center of rotation) and the grip 48 (operating portion) compared with the length between the shaft 54A and the fixing pin 42, allowing the main substrate 20 to slide with a small force.

Furthermore, a configuration without the grip 48 is also possible. When the first arm 52A is rotated in the arrow R1 direction, the first arm 52A may be directly pushed and rotated. Similarly, when the third arm 84 is rotated in the arrow R3 direction, the third arm 84 may be directly pushed and rotated. However, in a configuration with the grip 48, the grip 48 makes manipulation easy when the first arm 52A in the stored position is rotated in the direction opposite to the arrow R1 direction.

Furthermore, a configuration without the fix member (fixing pins 42) is possible. In a configuration without the fix member, for example, a pushing member may be used to slide the main substrate 20. However, in a configuration in which the main substrate 20 is slid by pushing, a pushing member for sliding the main substrate 20 in the arrow S2 direction and another pushing member for sliding the main substrate 20 in the opposite direction have to be provided. In contrast, by fixing the fix member to the main substrate 20, a force for movement may be applied from the fix member to the main substrate 20, both in the arrow S2 direction and the opposite direction.

Beside the above-described fixing pins 42, the fix member may be pinch members, such as clips, that are provided on the second arms 62A and 62B and are fixed by pinching the main substrate 20.

As illustrated in FIGS. 4A to 4C and 8A to 8C, by providing the fix members at two positions in the direction perpendicular to the sliding direction, the main substrates 20 may be slid with less rattling, compared with a configuration in which the fix member is provided at one position.

In the above-described configuration, the moving mechanism 40 is provided on the unit base 30. However, the moving mechanism 40 may be provided on the housing 16. That is, a configuration is possible in which, after the unit base 30 supporting the main substrate 20 is inserted into the housing 16, the moving mechanism 40 provided on the housing 16 is manipulated to slide the main substrate 20 in the arrow S2 direction so as to be electrically connected to the connection substrate 24. In this way, by providing the moving mechanism 40 on the unit base 30, the configuration of the housing 16 may be simplified. Furthermore, by using the unit base 30 compatible with various sizes and shapes of the main substrates 20, it is easy to cope with various sizes and shapes of the main substrates 20.

Although the electronic device 12 described above has a configuration in which the housing 16 accommodates a plurality of substrate units 18 arranged in the vertical direction, the housing 16 may accommodate only one substrate unit 18 in the vertical direction. However, by adopting a configuration in which the housing 16 accommodates a plurality of substrate units 18 arranged in the thickness direction, the space in the housing 16 is efficiently used.

Examples of the electronic device 12 include server devices and large computers, although not specifically limited thereto. For example, in the case of a server device, it is possible to realize a server device in which the main substrates 20 each function as a server and are connected to each other via the connection substrate 24.

Furthermore, the electronic device is not limited to those for processing information, but may be, for example, a power supply device or the like that stably supplies power to another external device. Such a power supply device has, in the housing, a substrate unit provided with devices, such as a transducer, a capacitor, and an inverter.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a housing;
a holder configured to support a first substrate and is inserted into the housing;
a second substrate disposed in the housing, at a side with respect to a direction in which the holder is inserted; and
a mechanism configured to move the first substrate in the direction with the second substrate and to connect the first substrate to the second substrate.

2. The electronic device according to claim 1, wherein the mechanism is provided over the holder.

3. The electronic device according to claim 2,
wherein the mechanism includes
a fix member that is fixed to the first substrate and is provided on the holder so as to be capable of movement; and
a manipulation member with which the fix member is manipulated and moved to the side.

4. The electronic device according to claim 3,
wherein the manipulation member includes
a link mechanism that is rotatably attached to the holder;
a grip that is provided on the link mechanism; and
a conversion mechanism configured to convert the rotation of the link mechanism into the movement of the fix member.

5. The electronic device according to claim 4, wherein the grip is located to a near side with respect to the direction in which the holder is inserted into the housing.

6. The electronic device according to claim 4, wherein the link mechanism is accommodated in the holder, in a state in which the fix member is located at the side.

7. The electronic device according to claim 6, further comprising a lock member that locks the link mechanism inside the holder.

8. The electronic device according to claim 4, wherein a plurality of the grips are provided.

9. A substrate container comprising:
a holder configured to support a first substrate and is inserted into a housing;
a fix member that is fixed to the first substrate and is provided on the holder so as to be capable of movement; and
a manipulation member with which the fix member is manipulated and moved to the side with respect to a direction in which the holder is inserted into the housing.

10. The substrate container according to claim 9,
wherein the manipulation member includes
a link mechanism that is rotatably attached to the holder;
a grip that is provided on the link mechanism; and
a conversion mechanism that converts the rotation of the link mechanism into the movement of the fix member.

11. The substrate container according to claim 10, wherein the grip is located to a near side with respect to the direction in which the holder is inserted into the housing.

12. The substrate container according to claim 10, wherein the link mechanism is accommodated in the holder, in a state in which the fix member is located at the side.

13. The substrate container according to claim 12, further comprising:
a lock member that locks the link mechanism inside the holder.

14. The substrate container according to claim 10, wherein a plurality of the grips are provided.
